(19) United States
(12) Patent Application Publication
(10) Pub. No.: US 2007/0035026 A1
(43) Pub. Date: Feb. 15, 2007

(54) Via in semiconductor device

(75) Inventors: Yi-Nien Su, Kaohsiung (TW); Jyu-Horng Shieh, Hsin-Chu (TW); Cheng-Lin Huang, Hsinchu (TW); Jing-Cheng Lin, Hsinchu (TW); Ching-Hua Hsieh, Hsinchu (TW); Shau-Lin Shue, Hsinchu (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/203,237

(22) Filed: Aug. 15, 2005

(51) Int. Cl. H01L 23/52; H01L 23/48; H01L 29/40

(52) U.S. Cl. 257/758

(57) ABSTRACT

An opening in a semiconductor device with improved step coverage. The opening comprises a dielectric layer overlying a substrate, having at least one via opening to expose the substrate. The via opening comprises a step region in the upper portion of the via opening and a concave profile region with respect to the dielectric layer in the lower portion of the via opening. A semiconductor device with the opening is also disclosed.

### BACKGROUND

The present invention relates to a semiconductor device, and particularly to a via in a semiconductor device with lowered aspect ratio and good step coverage for deposition of a barrier layer.

In semiconductor integrated circuit fabrication, a contact is formed to electrically connect an active region or a conductive layer formed in a semiconductor substrate with a metal interconnect line formed on a dielectric layer disposed between the interconnect line and the substrate. In forming the contact, a contact or via hole is typically formed in the dielectric layer to expose the active region or the conductive layer, with a conductive plug providing the inter-layer conductive path from the active region or the conductive layer to the interconnect line. A barrier layer commonly covers the contact or via hole in a uniform conformal form, preventing interdiffusion between the dielectric layer and the conductive plug, the active region or the conductive layer.

With development of high density integrated circuit technology, more components require placement on a chip, increasing complexity of the fabrication process as well as contact densities and aspect ratios. Increasing circuit density has also resulted in increased aspect ratios for contact and via holes. Higher aspect ratios, however, have a negative effect on fabrication yields because the contact or via holes require good metal step coverage to ensure reliable electrical contact. That is, as the aspect ratio increases, barrier layer deposition fails to produce good step coverage due to necking at the top corners of contact or via holes.

U.S. Pat. No. 4,830,974 to Chang et al. discloses an EPROM fabrication process. In this method, the top corners of contact or via holes are rounded in order to improve metal step coverage. U.S. Pat. No. 5,567,650 to Straight et al. discloses a method of forming a tapered plug-filled via. In this method, a tapered shape is formed at the intersection of the via hole and the upper surface of the dielectric layer, providing improved step coverage. U.S. Pat. No. 5,219,792 to Kim et al. discloses a method for forming multilevel interconnection in a semiconductor device. In this method, a flared corner for the via hole is employed to improve metal step coverage. Moreover, a spacer is formed on the sidewall of the via hole, thereby further improving metal step coverage.

### SUMMARY

An opening, for example a contact hole or a via hole, in a semiconductor device is provided. An embodiment of an opening in a semiconductor device comprises a dielectric layer overlying a substrate, having at least one via opening exposing the substrate. The via opening comprises a step region in the upper portion of the via opening and a concave profile region with respect to the dielectric layer in the lower portion.

An embodiment of a semiconductor device comprises a substrate having a conductive region therein, a dielectric layer overlying the substrate having at least one opening exposing the conductive region, and a metal layer disposed in the via opening and connecting to the conductive region. The opening comprises a step region in the upper portion of the opening and a concave profile region with respect to the dielectric layer in the lower portion. The opening further comprises a recess region in the bottom of the opening extending into the conductive region.

Another embodiment of a semiconductor device comprises a substrate having a conductive region therein, a dielectric layer overlying the substrate having at least one opening exposing the conductive region, and a metal layer disposed in the opening and connecting to the conductive region. The opening comprises two step regions in the upper portion of the opening and a recess region in the bottom of the opening extending into the conductive region.

### BRIEF DESCRIPTION OF THE DRAWINGS

The invention will become more fully understood from the detailed description given hereinbelow and the accompanying drawings, given by way of illustration only and thus not intended to be limitative of the invention.

FIG. 1 is a cross-section of an embodiment of a semiconductor device with an opening of the invention.

FIG. 2 is a cross-section of another embodiment of a semiconductor device with an opening of the invention.

FIG. 3 is a cross-section of another embodiment of a semiconductor device with an opening of the invention.

### DESCRIPTION

As will be appreciated by persons skilled in the art from the discussion herein, the present invention has wide applicability to many manufacturers, factories and industries. For discussion purposes, the embodiments are made herein to semiconductor foundry manufacturing (i.e., wafer fabrication in an IC foundry). However, the present invention is not limited thereto.

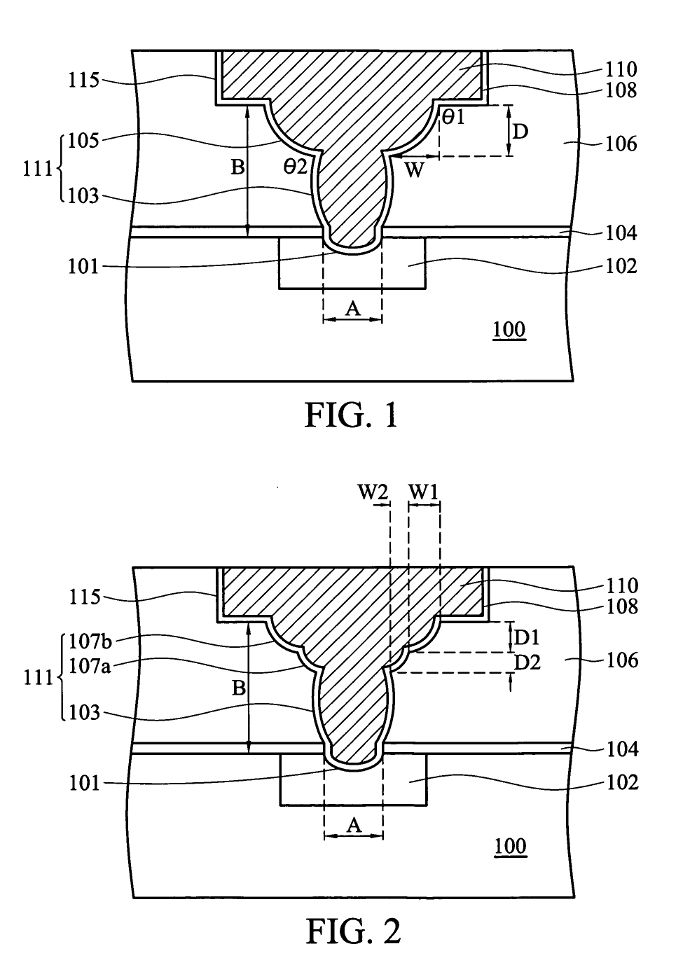

The invention relates to an improved via for a semiconductor device. FIG. 1 illustrates an embodiment of a semiconductor device with an opening, for example, a contact opening or a via opening. The semiconductor device comprises a substrate 100, a dielectric layer 106, and a metal layer 110. The substrate 100, such as a silicon substrate or other semiconductor substrate, may contain a variety of elements, including, for example, transistors, resistors, capacitors and other semiconductor elements as are well known in the art. The substrate 100 may also contain a conductive region 102, such as a doped region of a transistor or an inlaid metal layer. In this embodiment, the conductive region 102 is inlaid metal comprising copper, commonly used in the semiconductor industry for wiring discrete semiconductor devices in and on the substrate.

The dielectric layer 106, serving as an interlayer dielectric (ILD) layer or an intermetal dielectric (IMD) layer, overlies the substrate 100, having at least one damascene opening therein to expose the conductive region 102. The damascene opening may comprise a via opening, a trench opening, or combinations thereof. In this embodiment, the damascene opening comprises a via opening 111 and an overlying trench opening 115. Typically, the dielectric layer 106 may comprise a single material or hybrid materials. For example, the dielectric layer 106 comprises a single low dielectric constant (k) material to achieve low RC time constant (resistance-capacitance), wherein the dielectric layer 106 may comprise Si, C, N, and 0, having a dielectric constant less than 3 and even less than 2.5. Additionally, the dielectric layer 106 may comprises a porous material, such as carbon doped material, nitrogen doped material or hydrogen doped material. Moreover, a diffusion barrier or stop layer 104, such as a nitride containing layer or a carbon containing layer, is typically disposed between the substrate 100 and the dielectric layer 106.

In order to reduce the via aspect ratio, the via opening 111 may comprise a step region 105 with curved profile in the upper portion and a concave profile region 103 in the lower portion of the via opening 111. In this embodiment, the step region 105 has a depth D not greater than two-thirds of the depth B of the via opening 111 (D≦2B/3). Moreover, the step region 105 has a width W not exceeding twice the bottom width A of the via opening 111 and not less than half of the bottom width A of the via opening 111 (A/2≦W≦2A). The aspect ratio of the via opening 111 may be reduced to (B−D)/A from B/A. Accordingly, metal step coverage can be improved. Additionally, the step region 105 change both the top corner angle θ1 of the via opening 111 and the angle θ2 between the concave profile regions 105 and 103 to more than 90° (θ1, θ2>90°). As a result, metal step coverage is further improved since the upper and lower portions of the via opening 111 are formed with a concave profile with respect to the dielectric layer 106.

A recess region 101 may optionally be formed in the bottom of the via opening 111 extending into the conductive region 102, having a depth not less than 50 Å. The recess region 101 may mitigate the electron migration to further improve device reliability.

The metal layer 110, such as a copper layer, is filled in the trench opening 115, the via opening 111, and the underlying recess region 101, serving as an interconnect. In general, a thin metal barrier layer 108, such as titanium nitride (TiN), tantalum nitride (TaN) or tantalum (Ta) is conformally formed over the inner surfaces of the openings 115 and 111 and the recess region 101 prior to formation of the metal layer 110.

FIG. 2 illustrates another embodiment of a semiconductor device with an interconnect, in which the same reference numbers as FIG. 1 are used, wherefrom like descriptions are omitted. In FIG. 2, the semiconductor device also comprises a via opening 111 comprising two step regions with curved profile and a concave profile region 103 in the upper portion and lower portion of the via opening 111, respectively. In this embodiment, the two step regions may comprise at least two concave steps 107a and 107b with respect to the dielectric layer 106. The concave steps 107a and 107b have different depths and widths. For example, the depth D2 of the lower concave step 107a can be substantially less than the depth D1 of the upper concave step 107b. Moreover, the width W2 of the lower concave step 107a is substantially less than the width W1 of the upper concave step 107b. The width of the concave step 107a or 107b is substantially equal or less than the bottom width A of the via opening 111. Moreover, the depth of the concave step 107a or 107b is substantially less than half of the depth B of the via opening 111. The aspect ratio of the via opening 111 may be reduced to (B−D1−D2)/A from B/A. Accordingly, metal step coverage is improved. Also, the metal step coverage can be further improved since the upper portion of the via opening 111 is formed with a dual concave profile with respect to the dielectric layer 106.

A recess region 101 may also be formed in the bottom of the via opening 111 extending to the conductive region 102. As mentioned, the recess region 101 may mitigate electron migration to further improve device reliability.

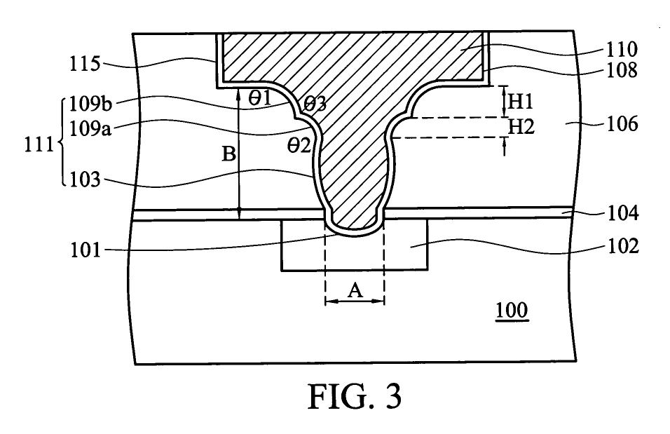

FIG. 3 illustrates further another embodiment of a semiconductor device with an interconnect, in which the same reference numbers as FIG. 1 are used, wherefrom like descriptions are omitted. In FIG. 3, the semiconductor device also comprises a via opening 111 comprising two step regions with curved profile. In this embodiment, the two step regions may comprise at least two convex steps 109a and 109b with respect to the dielectric layer 106. The lower convex step 109a has a height H2 and the upper convex step 109b a height H1. The height of one of the convex steps 109a and 109b does not exceed half the depth B of the via opening 111. The aspect ratio of the via opening 111 may be reduced to (B−H1−H2)/A from B/A. Accordingly, metal step coverage is improved. Additionally, the top corner angle θ1 of the via opening 111, the angle θ3 between the convex steps 109a and 109b, and the angle θ2 between the convex step 109a and the concave region 103 are all more than 90° (θ1, θ2, and θ3>90°). As a result, metal step coverage is further improved since the upper and lower portions of the via opening 111 are formed with a ladder profile and a concave profile with respect to the dielectric layer 106, respectively.

A recess region 101 may also be formed in the bottom of the via opening 111 extending to the conductive region 102 to mitigate the electron migration, thereby further improving device reliability.

While the invention has been described by way of example and in terms of preferred embodiment, it is to be understood that the invention is not limited thereto. To the contrary, it is intended to cover various modifications and similar arrangements (as would be apparent to those skilled in the art) Therefore, the scope of the appended claims should be accorded the broadest interpretation to encompass all such modifications and similar arrangements.

What is claimed is:

1. A opening in a semiconductor device, comprising:
a dielectric layer overlying a substrate, having at least one via opening to expose the substrate;
wherein the via opening comprises a step region in the upper portion of the via opening and a concave profile region with respect to the dielectric layer in the lower portion of the via opening.

2. The opening of claim 1, wherein the substrate further comprises a recess region substantially not less than 50 Å underlying the opening.

3. The opening of claim 1, wherein the step region comprises at least two concave steps with respect to the dielectric layer.

4. The opening of claim 3, wherein the depth of the lower concave step is substantially less than that of the upper concave step.

5. The opening of claim 3, wherein the lower concave step is substantially narrower than the upper concave step.

6. The opening of claim 3, wherein one of the concave step is substantially narrower than the bottom of the opening.

7. The opening of claim 3, wherein one of the concave steps is substantially less than half as deep as the opening.

8. The opening of claim 1, wherein the step region comprises at least two convex steps with respect to the dielectric layer.

9. The opening of claim 8, wherein one of the convex steps is not higher than half the depth of the opening.

10. The opening of claim 8, wherein an angle between the convex steps is not less than 90°.

11. A semiconductor device, comprising:
a substrate having a conductive region therein;
a dielectric layer overlying the substrate having at least one opening to expose the conductive region; and
a metal layer disposed in the opening, connecting to the conductive region;
wherein the opening comprises:
two step regions in the upper portion of the opening and a recess region in the bottom of the opening extending into the conductive region.

12. The semiconductor device of claim 11, wherein the recess region has a depth not less than 50 Å.

13. The semiconductor device of claim 11, wherein the two step regions comprise two concave steps with respect to the dielectric layer.

14. The semiconductor device of claim 11, wherein the dielectric layer comprises a low dielectric constant material comprising Si, C, N, and O.

15. The semiconductor device of claim 11, wherein the dielectric layer comprises a low dielectric constant material having a dielectric constant less than 3.

16. The semiconductor device of claim 13, wherein the lower concave step is substantially shallower than the upper concave step.

17. The semiconductor device of claim 13, wherein the lower concave step is substantially narrower than the upper concave step.

18. The semiconductor device of claim 13, wherein one of the concave steps is substantially narrower than the bottom of the opening.

19. The semiconductor device of claim 13, wherein one of the concave step is substantially less than half as deep as the opening.

20. The semiconductor device of claim 11, wherein the two step regions comprises two convex steps with respect to the dielectric layer.
